(19) United States
(12) Patent Application Publication
(10) Pub. No.: US 2019/0378956 A1
(43) Pub. Date: Dec. 12, 2019

(54) LIGHT EMITTING MODULE AND ITS PRODUCING METHOD

(71) Applicant: Lumileds Holding B.V., Schiphol (NL)

(72) Inventors: Kang Lu, Shanghai (CN); Hui-Kai Hsu, Shanghai (CN); Xiaoke Ren, Shanghai (CN); Meng Han, Shanghai (CN)

(21) Appl. No.: 16/434,041

(22) Filed: Jun. 6, 2019

(30) Foreign Application Priority Data
Jun. 6, 2018 (CN) PCT/CN2018/090028
Jul. 12, 2018 (EP) 18183066.2

(51) Int. Cl. H01L 33/44; F21S 41/141; F21S 41/32; F21S 41/43; H01L 33/50; H01L 33/62; H01L 33/20; H05K 3/28

(52) U.S. Cl. CPC H01L 33/44; F21S 41/141; F21S 41/321; F21S 41/43; F21Y 2115/10; H01L 33/62; H01L 33/20; H05K 3/284; H01L 33/504

(57) ABSTRACT

The present disclosure provides a light emitting module including: a substrate supporting at least one light emitting component; an enclosing component surrounding the light emitting component and defining an interspace between an inner surface of the enclosing component and the light emitting component; a coating material applied in the interspace between the enclosing component and the light emitting component. The enclosing component is attached as a separate component on the substrate. The light emitting module according to the present disclosure has an improved manufacturing effectiveness and convenience, and less complexity, thus reducing the production cost.

### CROSS REFERENCE TO RELATED APPLICATIONS

This application claims priority to International Application No. PCT/CN2018/090028 filed on Jun. 6, 2018 titled “LIGHT EMITTING MODULE AND ITS PRODUCING METHOD,” and claims priority to European Patent Application No. 18183066.2 filed on Jul. 12, 2018, and titled “LIGHT EMITTING MODULE AND ITS PRODUCING METHOD.” International Application No. PCT/CN2018/090028 and European Patent Application No. 18183066.2 are incorporated herein by reference.

### BACKGROUND OF THE DISCLOSURE

### 1. Field of the Disclosure

The present disclosure relates to the field of light emitting devices, specifically to a light emitting module for an automobile.

### 2. Description of the Prior Art

Currently, most of automotive LED lamps have an LED (as a light emitting component) with a side coating package. On one hand, the process to manufacture the side coating package is complicated and usually adopts a mold, which is expensive. If we would like to revise the side coating dimension, we have to redesign the mold. On the other hand, if we would like to dispense a curable side coating material around the LED package (level 1 light source) on a board to form a level 2 light source, we usually spin coat a curable coating material at an interval around the level 1 light source to form a glue dam and cure the glue dam, and then dispense the curable side coating material between the cured glue dam and the level 1 light source to form the level 2 light source. However, this method for manufacturing a level 2 light source from a level 1 light source, especially the step of curing the glue dam, spends much lead time increasing the production cost.

Therefore, it is desirable to provide an improved light emitting module for an automobile at least partially alleviating above problems.

### SUMMARY OF THE DISCLOSURE

The object of the present disclosure is to provide a light emitting module improving on one or more of manufacturing effectiveness, convenience and complexity, thus reducing production cost.

In order to achieve the above-mentioned object, the present disclosure provides a light emitting module, which includes: a substrate supporting at least one light emitting component; an enclosing component surrounding the light emitting component and defining an interspace between an inner surface of the enclosing component and the light emitting component; and a coating material applied in the interspace between the enclosing component and the light emitting component. The enclosing component is attached as a separate component on the substrate.

Since the light emitting module according to this disclosure adopts a simple enclosing component (which may be a standardized mechanical part such as a plain washer) instead of a complicated mold, compared with a conventional art adopting a mold, the manufacturing cost is significantly reduced. In addition, if the enclosing component adopts a standardized mechanical part such as a plain washer, the amount of the curable side coating material can be easily controlled.

According to an embodiment of the disclosure, the substrate, supporting the light emitting component, the enclosing component, and the coating material, is provided with a drive circuit for supplying the light emitting component with a drive voltage.

According to another embodiment of the disclosure, the light emitting component comprises an LED or an LED package and the coating material comprises a side coating for the LED or LED package.

According to a further embodiment of the disclosure, the LED is a top-emitting LED or the LED package is a top-emitting LED package for emission of light substantially perpendicular to a surface of the substrate.

As explained in the introduction, in the prior art, before applying the side coating material, a surrounding dam first has to be manufactured in a complicated process, e.g. by molding in a specifically designed mold or in a separate spin coating and curing process for forming a glue dam. In present invention, instead, the enclosing component is a separate, i.e., pre-fabricated, component that is only attached, during assembly of the light emitting module, onto the substrate. Such attachment can be done by the same processes and during the same assembly step as e.g. when attaching the light emitting component onto the substrate. In particular, pick-and-place PCB or lead-frame assembly machinery can be used, and, in preferred embodiments, the enclosing component can be glued or soldered onto the substrate.

According to another embodiment of the disclosure, the enclosing component is a plain washer.

According to still further embodiment of the disclosure, the plain washer is a standardized mechanical part and is made of metal.

However, the enclosing component might also be any other pre-fabricated component and might as well be made of (sufficiently durable) resin. In particular, any industry-standard and readily available component with appropriate dimensions and compatibility with the subsequent process steps, as e.g. dispensing and curing the side coating material, might be used.

According to an embodiment of the disclosure, the inner surface of the enclosing component is arranged for reflecting or scattering the emitted light from the light emitting component out of the interspace.

According to a further embodiment of the disclosure, the enclosing component has a circular or oval shape.

According to an embodiment of the disclosure, the coating material is a curable material that can be cured from soft to hard.

According to a further embodiment of the disclosure, the curable material is a curable resin or a curable phosphor glue.

According to an embodiment of the disclosure, the light emitting component is 0.05-5 mm in size and the enclosing component is 5-20 mm in size.

According to still another embodiment of the disclosure, the light emitting component is positioned at a center of the plain washer.

The present disclosure also provides a headlamp for an automobile comprising the aforementioned light emitting module.

The present disclosure also provides a method for producing a light emitting module, comprising steps of: providing a substrate; providing an enclosing component and at least one light emitting component on the substrate in such a way that the enclosing component surrounds the light emitting component; and applying a coating material in an interspace between an inner surface of the enclosing component and the light emitting component; wherein the enclosing component is attached as a separate component on the substrate.

Optionally, the coating material is a curable material, and the step of applying the coating material in the interspace comprises filling the curable material in the interspace and curing the curable material, and the step of curing the curable material comprises a step of heating the curable material at 150-180° C. for about 30 minutes or irradiating the curable material with light with a wavelength of 300-440 nm for about 10 seconds.

### BRIEF DESCRIPTION OF THE DRAWINGS

Specific implementations of a light emitting module of the present disclosure will be exemplarily illustrated below with reference to the figures. In addition, it should be noted that the illustration does not limit the present disclosure in any manner. In these figures:

FIG. 1 is a schematic perspective view of a light emitting module according to an embodiment of the present disclosure;

FIG. 2 is a top view of FIG. 1;

FIG. 3 is a side view of FIG. 1;

FIG. 4 is a bottom view of FIG. 1; and

FIG. 5 is an exploded view illustrating a manufacturing procedure of a light emitting module according to an embodiment of the present disclosure.

### DETAILED DESCRIPTION OF THE PRESENT DISCLOSURE

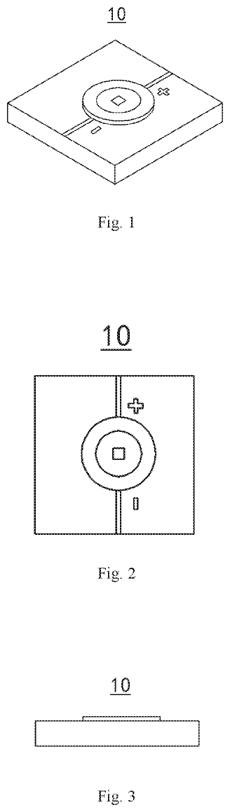

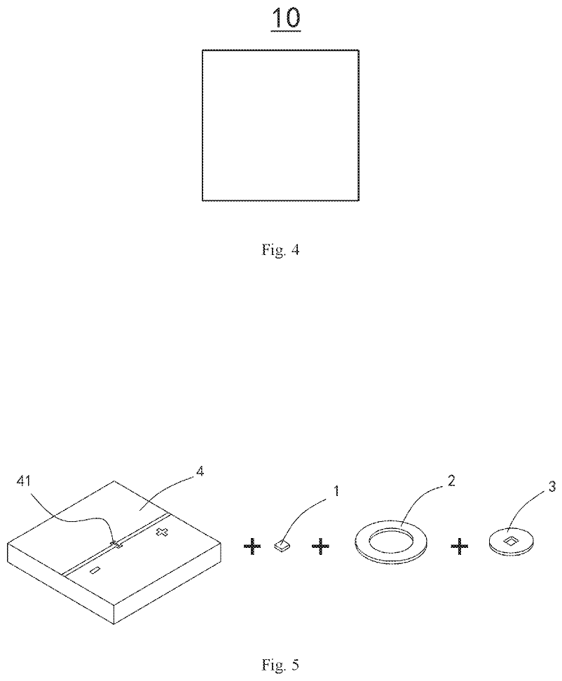

As shown in FIGS. 1-5, according to one aspect of the present disclosure, a light emitting module 10 for an automobile is provided. The light emitting module 10 includes: at least one light emitting component 1; an enclosing component 2 surrounding the light emitting component 1 and defining an interspace between an inner surface of the enclosing component 2 and the light emitting component 1; a coating material 3 applied in the interspace between the enclosing component 2 and the light emitting component 1; and a substrate 4 supporting the light emitting component 1, the enclosing component 2 and the coating material 3 and provided with a drive circuit 41 for supplying the light emitting component 1 with a drive voltage.

The light emitting component 1 may be 0.05-5 mm in size (the external profile size) and comprise an LED or an LED package. The LED may be a top-emitting LED or the LED package may be a top-emitting LED package for emission of light substantially perpendicular to a surface of the substrate 4.

The enclosing component 2 may be 5-20 mm in size (the external profile size) and can be any shape as long as it encloses the light emitting component 1 leaving enough space for the side coating material 3 filling. For instance, as shown in FIG. 5, the enclosing component 2 may be a ring-shaped plain washer, which is a standardized mechanical part and is made of metal. Preferably, the light emitting component 2 is positioned at a center of the plain washer. The inner surface of the enclosing component 2 is arranged for reflecting or scattering the emitted light from the light emitting component 1 out of the interspace. Optionally, the enclosing component 2 may have a circular or oval shape.

The coating material 3 may be 0.05-20 mm in size (the external profile size) and include a side coating for the LED or LED package. The coating material 3 may be a curable material that can be cured from soft to hard. As a choice, the curable material 3 may be a curable resin or a curable phosphor glue.

The present disclosure also provides a headlamp for an automobile, which comprises the aforementioned light emitting module 10.

The present disclosure also provides a method for producing a light emitting module 10, comprising the following steps: providing a substrate 4; providing an enclosing component 2 and at least one light emitting component 1 on the substrate 4 in such a way that the enclosing component 2 surrounds the light emitting component 1; and applying a coating material 3 in an interspace between an inner surface of the enclosing component 2 and the light emitting component 1. Optionally, the step of curing the curable material 3 comprises a step of heating the curable material 3 at 150-180° C. for about 30 minutes or irradiating the curable material 3 with light with a wavelength of 300-440 nm for about 10 seconds.

On one hand, since the light emitting module 10 according to the present disclosure attaches a simple separate enclosing component 2 (which may be a standardized mechanical part such as a plain washer) onto the substrate, instead of using a complicated mold, compared with a conventional art adopting a mold, the process to manufacture the side coating package is significantly simplified. If we would like to revise the side coating dimension, we only need to change the size of the plain washer and refilling the soft coating material around the LED or LED package. On the other hand, if we would like to dispense a curable side coating material around the LED package (level 1 light source) on a board to form a level 2 light source, we simply use the plain washer around the level 1 light source to form a metal dam instead of the spin-coated glue dam which needs a time-consuming curing in advance before filling coating material. Therefore, the manufacturing cost is significantly reduced. In addition, if the enclosing component 2 adopts a standardized mechanical part such as a plain washer, the amount of the curable side coating material 3 can be accurately controlled.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, number, and arrangement of parts within the principles of the disclosure to the full extent indicated by the broad general meaning of the terms in which the appended claims are expressed.

It should be noted that the abovementioned embodiments illustrate rather than limit the disclosure and that those skilled in the art would be able to design alternative embodiments without departing from the scope of the appended claims.

In the claims, the word “comprising” does not exclude the presence of elements or steps not listed in a claim or in the description. The word “a” or “an” preceding an element does not exclude the presence of a plurality of such elements. In the apparatus claims enumerating several units, several of these units can be embodied by one and the same item of hardware or software. The usage of the words first, second and third, et cetera, does not indicate any ordering. These words are to be interpreted as names.

Unless otherwise defined, all the technology and scientific terms used in the present description have the same meaning with those commonly understood by the skilled in the art where the present disclosure belongs to.

### LIST OF REFERENCE SIGNS

1 light emitting component
2 enclosing component
3 coating material
4 substrate
10 light emitting module
41 drive circuit

1. A light emitting module, comprising:
at least one light emitting component;
an enclosing component surrounding the light emitting component and defining an interspace between an inner surface of the enclosing component and the light emitting component;
a coating material applied in the interspace between the enclosing component and the light emitting component; and
a substrate supporting the light emitting component, the enclosing component and the coating material,
wherein the enclosing component is attached as a separate component on the substrate.

2. The light emitting module according to claim 1, further comprising a drive circuit, provided on the substrate, for supplying the light emitting component with a drive voltage.

3. The light emitting module according to claim 2, wherein the light emitting component comprises an LED or an LED package and the coating material comprises a side coating for the LED or LED package.

4. The light emitting module according to claim 3, wherein the LED is a top-emitting LED or the LED package is a top-emitting LED package for emission of light substantially perpendicular to a surface of the substrate.

5. The light emitting module according to claim 1, wherein the enclosing component is attached on the substrate by gluing or soldering.

6. The light emitting module according to claim 1, wherein the enclosing component is a plain washer and a standardized mechanical part made of metal.

7. The light emitting module according to claim 1, wherein the inner surface of the enclosing component is arranged for reflecting or scattering the emitted light from the light emitting component out of the interspace.

8. The light emitting module according to claim 1, wherein the enclosing component has a circular or oval shape.

9. The light emitting module according to claim 1, wherein the coating material is a curable material that can be cured from soft to hard.

10. The light emitting module according to claim 9, wherein the curable material is a curable resin or a curable phosphor glue.

11. The light emitting module according to claim 1, wherein the light emitting component is 0.05-5 mm in size and the enclosing component is 5-20 mm in size.

12. The light emitting module according to claim 6, wherein the light emitting component is positioned at a center of the plain washer.

13. A headlamp for an automobile comprising the light emitting module according to claim 1.

14. A method for producing a light emitting module, comprising steps of:
providing a substrate;
providing an enclosing component and at least one light emitting component on the substrate in such a way that the enclosing component surrounds the light emitting component; and
applying a coating material in an interspace between an inner surface of the enclosing component and the light emitting component,
wherein the enclosing component is attached as a separate component on the substrate.

15. The method of claim 14, wherein
the coating material is a curable material, and the step of applying the coating material in the interspace comprises filling the curable material in the interspace and curing the curable material, and
the step of curing the curable material comprises a step of heating the curable material at 150-180° C. for about 30 minutes or irradiating the curable material with light with a wavelength of 300-440 nm for about 10 seconds.
